(19) United States
(12) Patent Application Publication
(10) Pub. No.: US 2009/0045885 A1
(43) Pub. Date: Feb. 19, 2009

(54) PASSIVE STRUCTURE FOR HIGH POWER AND LOW LOSS APPLICATIONS

(75) Inventor: ALI SARFARAZ, ALAMO, CA (US)

Correspondence Address: GARLICK HARRISON & MARKISON, P.O. BOX 160727, AUSTIN, TX, 78716-0727, US

(73) Assignee: BROADCOM CORPORATION, IRVINE, CA (US)

(21) Appl. No.: 12/017,320

(22) Filed: Jan. 21, 2008

Related U.S. Application Data
(60) Provisional application No. 60/956,498, filed on Aug. 17, 2007.

(51) Int. Cl. H03H 5/00; H01F 5/00

(52) U.S. Cl. 333/25; 336/200

(57) ABSTRACT

An integrated circuit radio transceiver and method therefor includes a balun formed to have interleaved traces which is operable to satisfy high current density requirements while reducing resistive and capacitive reactance of the balun to minimize coupling losses and to maintain efficiency. The interleaved traces may be selectively coupled according to design and application requirements.

### CROSS-REFERENCE TO RELATED APPLICATION

The present U.S. Utility Patent Application claims priority pursuant to 35 U.S.C. §119(e) to the following U.S. Provisional Patent Application which is hereby incorporated herein by reference in its entirety and made part of the present U.S. Utility Patent Application for all purposes:
1. U.S. Provisional Application Ser. No. 60/956,498, entitled “Passive Structure for High Power and Low Loss Applications,” (Attorney Docket No. BP6640), filed Aug. 17, 2007, pending.

### BACKGROUND

1. Technical Field

The present invention relates to wireless communications and, more particularly, to circuitry for wireless communications.

2. Related Art

Communication systems are known to support wireless and wire lined communications between wireless and/or wire lined communication devices. Such communication systems range from national and/or international cellular telephone systems to the Internet to point-to-point in-home wireless networks. Each type of communication system is constructed, and hence operates, in accordance with one or more communication standards. For instance, wireless communication systems may operate in accordance with one or more standards, including, but not limited to, IEEE 802.11, Bluetooth, advanced mobile phone services (AMPS), digital AMPS, global system for mobile communications (GSM), code division multiple access (CDMA), local multi-point distribution systems (LMDS), multi-channel-multi-point distribution systems (MMDS), and/or variations thereof.

Depending on the type of wireless communication system, a wireless communication device, such as a cellular telephone, two-way radio, personal digital assistant (PDA), personal computer (PC), laptop computer, home entertainment equipment, etc., communicates directly or indirectly with other wireless communication devices. For direct communications (also known as point-to-point communications), the participating wireless communication devices tune their receivers and transmitters to the same channel or channels (e.g., one of a plurality of radio frequency (RF) carriers of the wireless communication system) and communicate over that channel(s). For indirect wireless communications, each wireless communication device communicates directly with an associated base station (e.g., for cellular services) and/or an associated access point (e.g., for an in-home or in-building wireless network) via an assigned channel. To complete a communication connection between the wireless communication devices, the associated base stations and/or associated access points communicate with each other directly, via a system controller, via a public switch telephone network (PSTN), via the Internet, and/or via some other wide area network.

Each wireless communication device includes a built-in radio transceiver (i.e., receiver and transmitter) or is coupled to an associated radio transceiver (e.g., a station for in-home and/or in-building wireless communication networks, RF modem, etc.). As is known, the transmitter includes a data modulation stage, one or more intermediate frequency stages, and a power amplifier stage. The data modulation stage converts raw data into baseband signals in accordance with the particular wireless communication standard. The one or more intermediate frequency stages mix the baseband signals with one or more local oscillations to produce RF signals. The power amplifier stage amplifies the RF signals prior to transmission via an antenna.

Typically, the data modulation stage is implemented on a baseband processor chip, while the intermediate frequency (IF) stages and power amplifier stage are implemented on a separate radio processor chip. Historically, radio integrated circuits have been designed using bi-polar circuitry, allowing for large signal swings and linear transmitter component behavior. Therefore, many legacy baseband processors employ analog interfaces that communicate analog signals to and from the radio processor.

In many radio frequency applications, baluns are used to couple singled ended circuit paths to differential circuit paths such as, for example, an antenna for a radio front end. Baluns are typically implemented to have a precise 180 phase shift with minimum loss and to provide equally balanced impedances. Traditional baluns are formed of wire-wound transformers for lower frequency applications. For higher frequency applications, miniature wire-wound transformers have been used. One issue relating to baluns, especially for higher frequencies, is that the reactive capacitance and inductance and overall impedance is based upon frequency. Accordingly, balun designs are typically tailored for a frequency of interest. Moreover, with ongoing demand for miniaturization, baluns and other circuit elements are desirably placed on chip. Thus, improved balun designs for on-chip baluns that improve balun performance are desirable.

### SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE DRAWINGS

A better understanding of the present invention can be obtained when the following detailed description of the preferred embodiment is considered with the following drawings, in which:

FIG. 1 is a schematic block diagram illustrating a wireless communication device that includes a host device and an associated radio;

FIG. 2 is a schematic block diagram illustrating a wireless communication host device and an associated radio;

FIG. 3 is a schematic block diagram illustrating a wireless communication device that includes the host device and an associated radio with a MIMO capable topology;

FIG. 4 is a functional block diagram of integrated circuit transceiver circuitry with a pair of baluns formed according to one embodiment of the invention;

FIG. 5 is a functional diagram of a balun comprising two strips arranged on the same plane or layer adjacent to each other with opposing edges;

FIG. 6 is an illustration of possible strip arrangements for a balun formed according to one embodiment and includes two strips arranged in a superimposed manner on different layers of an integrated circuit;

FIG. 7 illustrates a balun formed according to one embodiment of the invention having interlaced strips according to one embodiment of the invention;

FIG. 8 is a diagram illustrating a slice of a balun formed according to one embodiment of the invention;

FIG. 9 is a functional schematic diagram of a balun formed according to one embodiment of the invention;

FIG. 10 is a signal flow diagram that illustrates one possible secondary coil signal path; and

FIGS. 11 and 12 are flow charts that illustrate a method according to one embodiment of the invention.

### DETAILED DESCRIPTION OF THE DRAWINGS

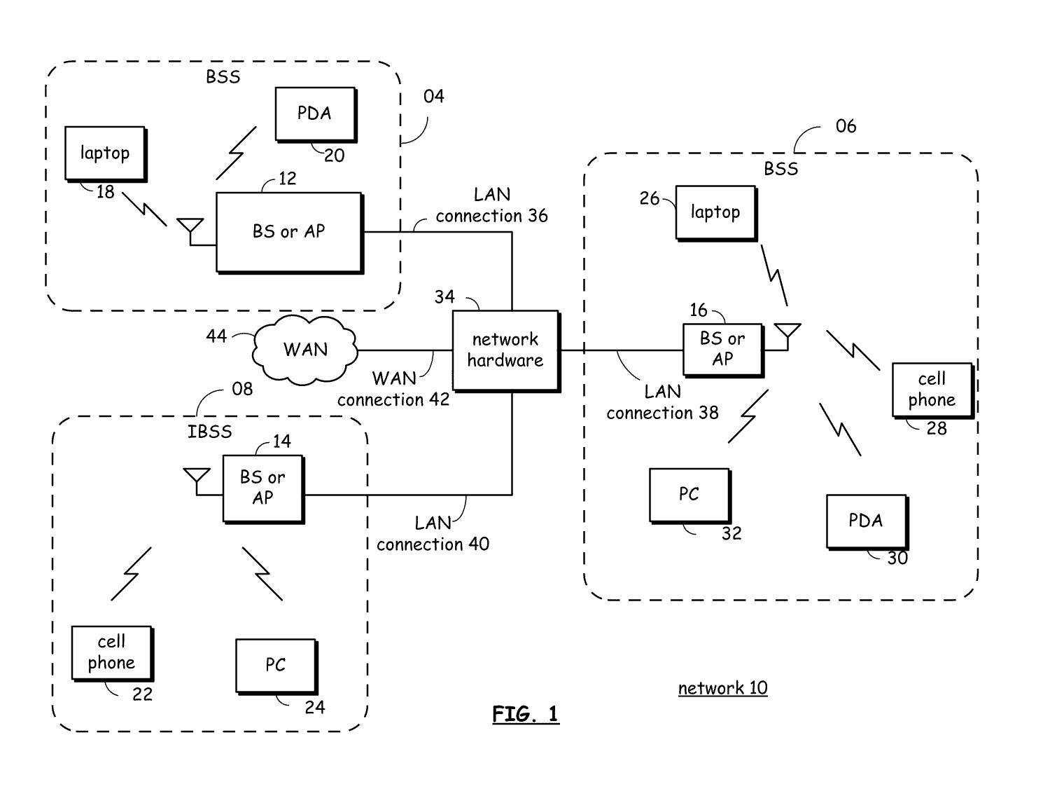

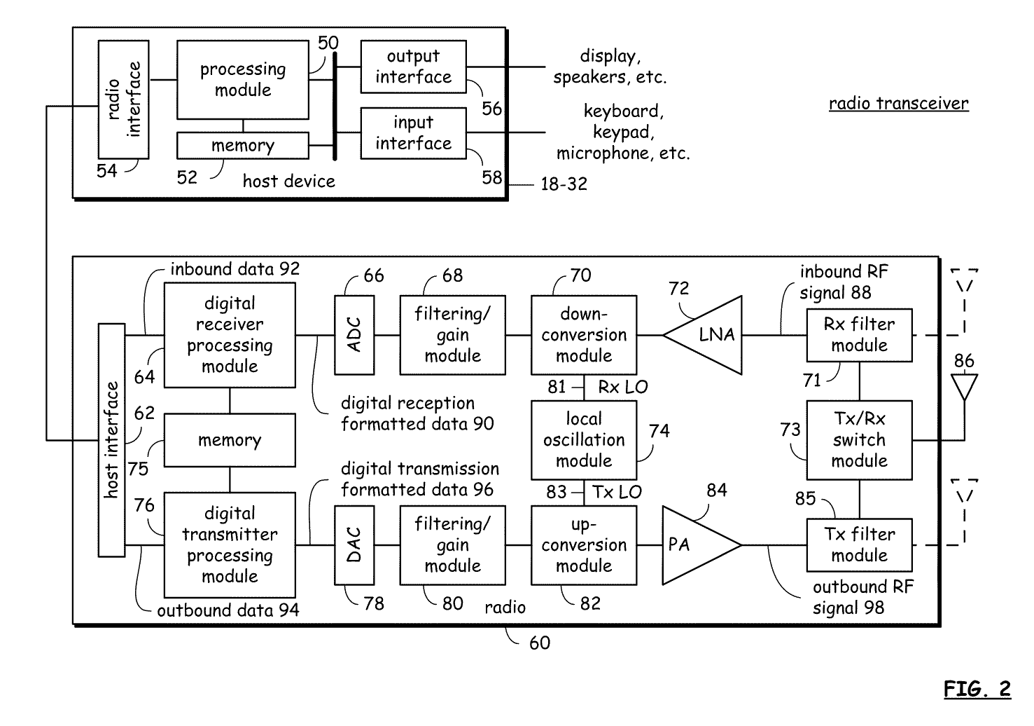

FIG. 1 is a functional block diagram illustrating a communication system that includes circuit devices and network elements and operation thereof according to one embodiment of the invention. More specifically, a plurality of network service areas 04, 06 and 08 are a part of a network 10. Network 10 includes a plurality of base stations (BS) or access points (AP) 12-16, a plurality of wireless communication devices 18-32 and a network hardware component 34. The wireless communication devices 18-32 may be laptop computers 18 and 26, personal digital assistants 20 and 30, personal computers 24 and 32 and/or cellular telephones 22 and 28. The details of the wireless communication devices will be described in greater detail with reference to FIGS. 2-10.

The base stations or APs 12-16 are operably coupled to the network hardware component 34 via local area network (LAN) connections 36, 38 and 40. The network hardware component 34, which may be a router, switch, bridge, modem, system controller, etc., provides a wide area network (WAN) connection 42 for the communication system 10 to an external network element such as WAN 44. Each of the base stations or access points 12-16 has an associated antenna or antenna array to communicate with the wireless communication devices in its area. Typically, the wireless communication devices 18-32 register with the particular base station or access points 12-16 to receive services from the communication system 10. For direct connections (i.e., point-to-point communications), wireless communication devices communicate directly via an allocated channel.

Typically, base stations are used for cellular telephone systems and like-type systems, while access points are used for in-home or in-building wireless networks. Regardless of the particular type of communication system, each wireless communication device includes a built-in radio and/or is coupled to a radio.

FIG. 2 is a schematic block diagram illustrating a wireless communication host device 18-32 and an associated radio 60. For cellular telephone hosts, radio 60 is a built-in component. For personal digital assistants hosts, laptop hosts, and/or personal computer hosts, the radio 60 may be built-in or an externally coupled component.

As illustrated, wireless communication host device 18-32 includes a processing module 50, a memory 52, a radio interface 54, an input interface 58 and an output interface 56. Processing module 50 and memory 52 execute the corresponding instructions that are typically done by the host device. For example, for a cellular telephone host device, processing module 50 performs the corresponding communication functions in accordance with a particular cellular telephone standard.

Radio interface 54 allows data to be received from and sent to radio 60. For data received from radio 60 (e.g., inbound data), radio interface 54 provides the data to processing module 50 for further processing and/or routing to output interface 56. Output interface 56 provides connectivity to an output device such as a display, monitor, speakers, etc., such that the received data may be displayed. Radio interface 54 also provides data from processing module 50 to radio 60. Processing module 50 may receive the outbound data from an input device such as a keyboard, keypad, microphone, etc., via input interface 58 or generate the data itself. For data received via input interface 58, processing module 50 may perform a corresponding host function on the data and/or route it to radio 60 via radio interface 54.

Radio 60 includes a host interface 62, a digital receiver processing module 64, an analog-to-digital converter (ADC) 66, a filtering/gain module 68, a down-conversion module 70, a low noise amplifier (LNA) 72, a receiver filter module 71, a transmitter/receiver (Tx/Rx) switch module 73, a local oscillation module 74, a memory 75, a digital transmitter processing module 76, a digital-to-analog converter (DAC) 78, a filtering/gain module 80, an up-conversion module 82, a power amplifier 84, a transmitter filter module 85, and an antenna 86 operatively coupled as shown. The antenna 86 is shared by the transmit and receive paths as regulated by the Tx/Rx switch module 73. The antenna implementation will depend on the particular standard to which the wireless communication device is compliant.

Digital receiver processing module 64 and digital transmitter processing module 76, in combination with operational instructions stored in memory 75, execute digital receiver functions and digital transmitter functions, respectively. The digital receiver functions include, but are not limited to, demodulation, constellation demapping, decoding, and/or descrambling. The digital transmitter functions include, but are not limited to, scrambling, encoding, constellation mapping, and modulation. Digital receiver and transmitter processing modules 64 and 76, respectively, may be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions.

Memory 75 may be a single memory device or a plurality of memory devices. Such a memory device may be a read-only memory, random access memory, volatile memory, non-volatile memory, static memory, dynamic memory, flash memory, and/or any device that stores digital information. Note that when digital receiver processing module 64 and/or digital transmitter processing module 76 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry. Memory 75 stores, and digital receiver processing module 64 and/or digital transmitter processing module 76 executes, operational instructions corresponding to at least some of the functions illustrated herein.

In operation, radio 60 receives outbound data 94 from wireless communication host device 18-32 via host interface 62. Host interface 62 routes outbound data 94 to digital transmitter processing module 76, which processes outbound data 94 in accordance with a particular wireless communication standard or protocol (e.g., IEEE 802.11(a), IEEE 802.11b, Bluetooth, etc.) to produce digital transmission formatted data 96. Digital transmission formatted data 96 will be a digital baseband signal or a digital low IF signal, where the low IF typically will be in the frequency range of one hundred kilohertz to a few megahertz.

Digital-to-analog converter 78 converts digital transmission formatted data 96 from the digital domain to the analog domain. Filtering/gain module 80 filters and/or adjusts the gain of the analog baseband signal prior to providing it to up-conversion module 82. Up-conversion module 82 directly converts the analog baseband signal, or low IF signal, into an RF signal based on a transmitter local oscillation 83 provided by local oscillation (LO) module 74. Power amplifier (PA) 84 amplifies the RF signal to produce an outbound RF signal 98, which is filtered by transmitter filter module 85. The antenna 86 transmits outbound RF signal 98 to a targeted device such as a base station, an access point and/or another wireless communication device.

Radio 60 also receives an inbound RF signal 88 via antenna 86, which was transmitted by a base station, an access point, or another wireless communication device. The antenna 86 provides inbound RF signal 88 to receiver filter module 71 via Tx/Rx switch module 73, where Rx filter module 71 bandpass filters inbound RF signal 88. The Rx filter module 71 provides the filtered RF signal to low noise amplifier 72, which amplifies inbound RF signal 88 to produce an amplified inbound RF signal. Low noise amplifier 72 provides the amplified inbound RF signal to down-conversion module 70, which directly converts the amplified inbound RF signal into an inbound low IF signal or baseband signal based on a receiver local oscillation 81 provided by local oscillation module 74. Down-conversion module 70 provides the inbound low IF signal or baseband signal to filtering/gain module 68. Filtering/gain module 68 may be implemented in accordance with the teachings of the present invention to filter and/or attenuate the inbound low IF signal or the inbound baseband signal to produce a filtered inbound signal.

Analog-to-digital converter 66 converts the filtered inbound signal from the analog domain to the digital domain to produce digital reception formatted data 90. Digital receiver processing module 64 decodes, descrambles, demaps, and/or demodulates digital reception formatted data 90 to recapture inbound data 92 in accordance with the particular wireless communication standard being implemented by radio 60. Host interface 62 provides the recaptured inbound data 92 to the wireless communication host device 18-32 via radio interface 54.

As one of average skill in the art will appreciate, the wireless communication device of FIG. 2 may be implemented using one or more integrated circuits. For example, the host device may be implemented on a first integrated circuit, while digital receiver processing module 64, digital transmitter processing module 76 and memory 75 may be implemented on a second integrated circuit, and the remaining components of radio 60, less antenna 86, may be implemented on a third integrated circuit. As an alternate example, radio 60 may be implemented on a single integrated circuit. As yet another example, processing module 50 of the host device and digital receiver processing module 64 and digital transmitter processing module 76 may be a common processing device implemented on a single integrated circuit.

Memory 52 and memory 75 may be implemented on a single integrated circuit and/or on the same integrated circuit as the common processing modules of processing module 50, digital receiver processing module 64, and digital transmitter processing module 76. As will be described, it is important that accurate oscillation signals are provided to mixers and conversion modules. A source of oscillation error is noise coupled into oscillation circuitry through integrated circuitry biasing circuitry. One embodiment of the present invention reduces the noise by providing a selectable pole low pass filter in current mirror devices formed within the one or more integrated circuits.

Local oscillation module 74 includes circuitry for adjusting an output frequency of a local oscillation signal provided therefrom. Local oscillation module 74 receives a frequency correction input that it uses to adjust an output local oscillation signal to produce a frequency corrected local oscillation signal output. While local oscillation module 74, up-conversion module 82 and down-conversion module 70 are implemented to perform direct conversion between baseband and RF, it is understood that the principles herein may also be applied readily to systems that implement an intermediate frequency conversion step at a low intermediate frequency.

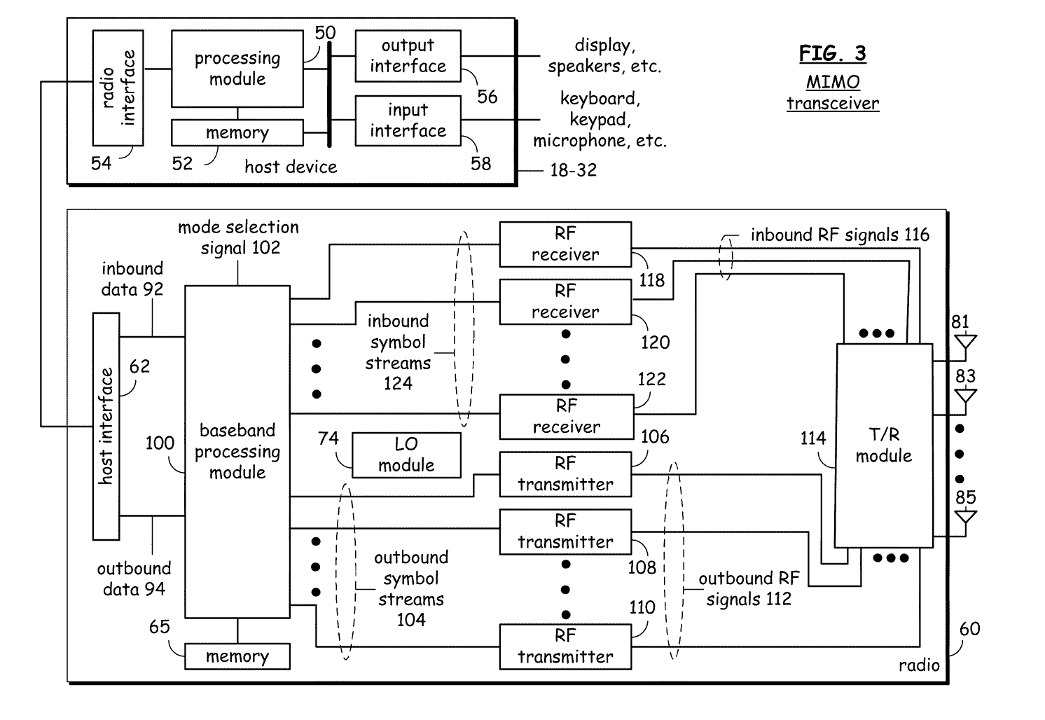

FIG. 3 is a schematic block diagram illustrating a wireless communication device that includes the host device 18-32 and an associated radio 60. For cellular telephone hosts, the radio 60 is a built-in component. For personal digital assistants hosts, laptop hosts, and/or personal computer hosts, the radio 60 may be built-in or an externally coupled component.

As illustrated, the host device 18-32 includes a processing module 50, memory 52, radio interface 54, input interface 58 and output interface 56. The processing module 50 and memory 52 execute the corresponding instructions that are typically done by the host device. For example, for a cellular telephone host device, the processing module 50 performs the corresponding communication functions in accordance with a particular cellular telephone standard.

The radio interface 54 allows data to be received from and sent to the radio 60. For data received from the radio 60 (e.g., inbound data), the radio interface 54 provides the data to the processing module 50 for further processing and/or routing to the output interface 56. The output interface 56 provides connectivity to an output display device such as a display, monitor, speakers, etc., such that the received data may be displayed. The radio interface 54 also provides data from the processing module 50 to the radio 60. The processing module 50 may receive the outbound data from an input device such as a keyboard, keypad, microphone, etc., via the input interface 58 or generate the data itself. For data received via the input interface 58, the processing module 50 may perform a corresponding host function on the data and/or route it to the radio 60 via the radio interface 54.

Radio 60 includes a host interface 62, a baseband processing module 100, memory 65, a plurality of radio frequency (RF) transmitters 106-110, a transmit/receive (T/R) module 114, a plurality of antennas 81-85, a plurality of RF receivers 118-120, and a local oscillation module 74. The baseband processing module 100, in combination with operational instructions stored in memory 65, executes digital receiver functions and digital transmitter functions, respectively. The digital receiver functions include, but are not limited to, digital intermediate frequency to baseband conversion, demodulation, constellation demapping, decoding, de-interleaving, fast Fourier transform, cyclic prefix removal, space and time decoding, and/or descrambling. The digital transmitter functions include, but are not limited to, scrambling, encoding, interleaving, constellation mapping, modulation, inverse fast Fourier transform, cyclic prefix addition, space and time encoding, and digital baseband to IF conversion. The baseband processing module 100 may be implemented using one or more processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 65 may be a single memory device or a plurality of memory devices. Such a memory device may be a read-only memory, random access memory, volatile memory, non-volatile memory, static memory, dynamic memory, flash memory, and/or any device that stores digital information. Note that when the baseband processing module 100 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

In operation, the radio 60 receives outbound data 94 from the host device via the host interface 62. The baseband processing module 100 receives the outbound data 94 and, based on a mode selection signal 102, produces one or more outbound symbol streams 104. The mode selection signal 102 will indicate a particular mode of operation that is compliant with one or more specific modes of the various IEEE 802.11 standards. For example, the mode selection signal 102 may indicate a frequency band of 2.4 GHz, a channel bandwidth of 20 or 22 MHz and a maximum bit rate of 54 megabits-per-second. In this general category, the mode selection signal will further indicate a particular rate ranging from 1 megabit-per-second to 54 megabits-per-second. In addition, the mode selection signal will indicate a particular type of modulation, which includes, but is not limited to, Barker Code Modulation, BPSK, QPSK, CCK, 16 QAM and/or 64 QAM. The mode selection signal 102 may also include a code rate, a number of coded bits per subcarrier (NBPSC), coded bits per OFDM symbol (NCBPS), and/or data bits per OFDM symbol (NDBPS). The mode selection signal 102 may also indicate a particular channelization for the corresponding mode that provides a channel number and corresponding center frequency. The mode selection signal 102 may further indicate a power spectral density mask value and a number of antennas to be initially used for a MIMO communication.

The baseband processing module 100, based on the mode selection signal 102 produces one or more outbound symbol streams 104 from the outbound data 94. For example, if the mode selection signal 102 indicates that a single transmit antenna is being utilized for the particular mode that has been selected, the baseband processing module 100 will produce a single outbound symbol stream 104. Alternatively, if the mode selection signal 102 indicates 2, 3 or 4 antennas, the baseband processing module 100 will produce 2, 3 or 4 outbound symbol streams 104 from the outbound data 94.

Depending on the number of outbound symbol streams 104 produced by the baseband processing module 100, a corresponding number of the RF transmitters 106-110 will be enabled to convert the outbound symbol streams 104 into outbound RF signals 112. In general, each of the RF transmitters 106-110 includes a digital filter and upsampling module, a digital-to-analog conversion module, an analog filter module, a frequency up conversion module, a power amplifier, and a radio frequency bandpass filter. The RF transmitters 106-110 provide the outbound RF signals 112 to the transmit/receive module 114, which provides each outbound RF signal to a corresponding antenna 81-85.

When the radio 60 is in the receive mode, the transmit/receive module 114 receives one or more inbound RF signals 116 via the antennas 81-85 and provides them to one or more RF receivers 118-122. The RF receiver 118-122 converts the inbound RF signals 116 into a corresponding number of inbound symbol streams 124. The number of inbound symbol streams 124 will correspond to the particular mode in which the data was received. The baseband processing module 100 converts the inbound symbol streams 124 into inbound data 92, which is provided to the host device 18-32 via the host interface 62.

As one of average skill in the art will appreciate, the wireless communication device of FIG. 3 may be implemented using one or more integrated circuits. For example, the host device may be implemented on a first integrated circuit, the baseband processing module 100 and memory 65 may be implemented on a second integrated circuit, and the remaining components of the radio 60, less the antennas 81-85, may be implemented on a third integrated circuit. As an alternate example, the radio 60 may be implemented on a single integrated circuit. As yet another example, the processing module 50 of the host device and the baseband processing module 100 may be a common processing device implemented on a single integrated circuit. Further, the memory 52 and memory 65 may be implemented on a single integrated circuit and/or on the same integrated circuit as the common processing modules of processing module 50 and the baseband processing module 100.

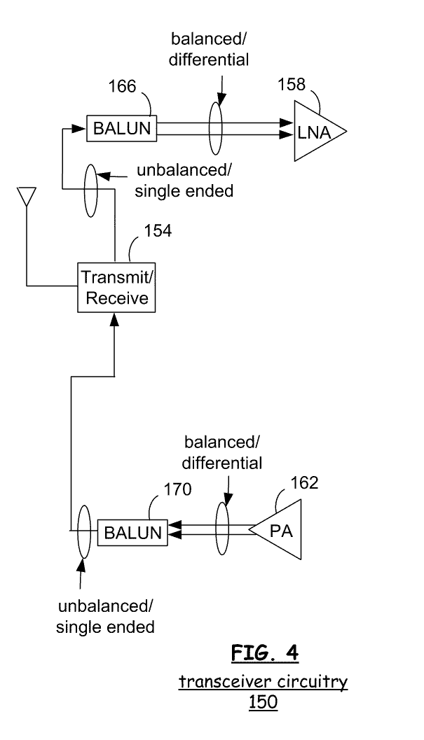

FIG. 4 is a functional block diagram of integrated circuit transceiver circuitry with a pair of baluns formed according to one embodiment of the invention. Transceiver circuitry 150 includes a transmit-receive switch 154 that is operable to couple at least one antenna to receive path and transmit path circuitry. For simplicity, only a receive path low noise amplifier 158 is shown for the receive path and a transmit path power amplifier 162 is shown for the transmit path. It should be understood that the single in single out (SISO) configuration shown may readily be modified to support multiple in multiple out (MIMO) and other multiple signal path configurations. Low noise amplifier 158 and power amplifier 162 are part of radio frequency front circuitry not shown here but similar to that shown in FIGS. 2 and 3.

Disposed between transmit-receive switch 154 and low noise amplifier 158 is balun 166. As may be seen, balun 166 receives a single ended input from transmit-receive switch 154 and produces a differential output to low noise amplifier 158. Similarly, balun 170 is disposed between power amplifier 162 transmit-receive switch 154. Balun 170 includes a differential input and a single-ended output. In an alternate embodiment, a single balun is disposed between a single antenna and a differential transmit-receive switch that is operable to perform differential switching between the balun and the receive and transmit paths.

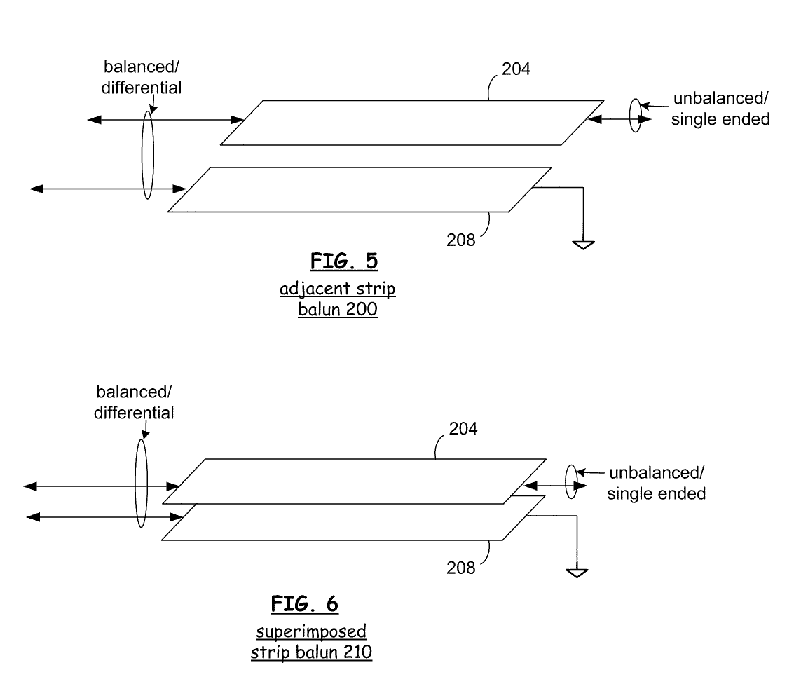

FIGS. 5 and 6 are functional block diagrams of different configurations for baluns using micro-strips that may be utilized in portions of the balun designs according to at least one embodiment of the invention. More specifically, FIG. 5 is a functional diagram of a balun comprising two strips arranged on the same plane or layer adjacent to each other with opposing edges. In FIG. 5, a balun 200 comprises strips 204 and 208 arranged on the same plane or layer adjacent to each other with opposing edges. As may be seen, one end of the balun 200 is single ended (so called “unbalanced”) and a second end is differential (“balanced”). Strip 208 is coupled to ground at one end and is coupled to receive or produce signals at the other end while strip 204 is coupled to receive or produce signals at both ends. Based upon factors such as frequency, strip dimensions, current intensity, etc., the strips are magnetically and/or electrically coupled based upon the separation between the two strips. The inductive, capacitive and resistive aspects of the strips 204 and 208 and, more generally, of the balun 200, are based upon the strip dimensions and construction.

FIG. 6 is an illustration of possible strip arrangements for a balun 210 formed according to one embodiment and includes two strips arranged in a superimposed manner on different layers of an integrated circuit. For a common separation distance, two strips 204 and 208 arranged as shown in FIG. 6 provide better electrical or magnetic coupling that the arrangement of FIG. 5. Such an embodiment, however, has higher associated fabrication and IC real estate costs.

Generally, FIGS. 5 and 6 illustrate relative placement of strips of a balun though it should be understood that the total number of strips will typically be greater than two for some embodiments of the invention. Moreover, as shown in Figures that follow, the multiple strips of a pair of coils may be interlaced to improve overall operation by reducing resistive, inductive and capacitive losses. Thus, for example, a plurality of strips arranged on the same plane with opposing edges, as illustrated in FIG. 5, may be used to create the interlaced coils of a balun to provide improved operation.

FIG. 7 illustrates a balun 250 formed according to one embodiment of the invention having interlaced strips according to one embodiment of the invention. In an application in which current density requirements are high (e.g., 300 mA), a wide strip is typically required to carry the high current levels. At the higher frequencies, however, wider strips create substantially higher capacitance or capacitive reactance. If narrow strips are used, however, the strips cannot satisfy the higher current density requirements. The embodiment of FIG. 7, however, by using a plurality of interlaced strips for two different “coils” of a balun, satisfies higher current density requirements while improving coupling (decreasing coupling loss), reducing resistance and reducing capacitance. As may be seen, the strips are interlaced by placing one group of strips in the slots between a second group of strips. Thus, at least one strip is interlaced and placed in a slot between two coupled strips.

In the specific embodiment of FIG. 7, one end of a plurality of strips are necessarily coupled while the opposite end is optionally coupled for each group of strips as shown. Thus, in addition to the interlaced strips that are shown to be coupled at one end, FIG. 7 shows optional coupling 254 at the opposite end for each group of interlaced strips. As such, according to design requirements, coupling of strips may be selected according to design and application requirements.

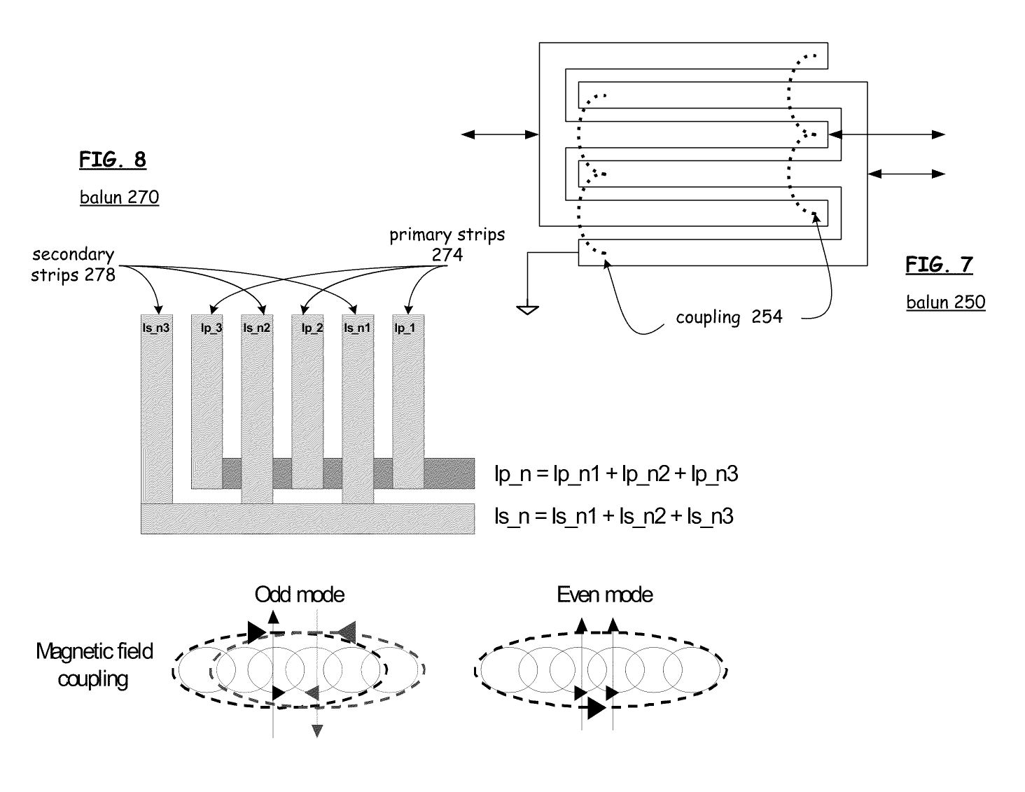

FIG. 8 is a diagram illustrating a slice of a balun 270 formed according to one embodiment of the invention. As may be seen, strips (primary strips 274) of a primary coil (lp) are interlaced with strips (secondary strips 278) of a secondary coil. The total current Ipor Is for the primary and secondary coils, respectively, is a sum of the currents (Ip_n1, Ip_n2, Ip_n3, Is_n1, Is_n2, and Is_n3) in the corresponding interlaced branches as shown in FIG. 8. FIG. 8 further illustrates even and odd modes of operation and the corresponding flux patterns based upon whether the primary and secondary coils are conducting current in the same or opposite directions. Generally, even coupling results in inductive coupling while odd coupling results in capacitive coupling.

FIG. 9 is a functional schematic diagram of a balun 300 formed according to one embodiment of the invention. The primary coil and secondary coil traces 274 and 278, respectively, carry currents Ip and Is and are formed, in the described embodiment, on the same layer or plane relative to each other. As described in relation to the preceding figures, the embodiment of FIG. 9 includes a plurality of strips to increase current capacity while maintaining low capacitance and resistance. For higher frequency applications, less turns are required in the coils to create the desired levels of inductive or magnetic coupling. As such, the balun 300 of FIG. 9 includes a plurality of strips arranged in a coil about a center core. The coupling and number of strips is variable. In the embodiment of FIG. 9, the strips are coupled to provide two current paths in one direction and one current path in an opposite direction for the balanced and unbalanced ends of the balun. In one particular application, the unbalanced side carries a direct current while the balanced end carries an alternating current comprising the signal being transmitted or received. Further, in this particular embodiment, inductance may be increased by increasing the number of coupled branches or strips on the primary side.

In another embodiment, the primary coil comprises four strips with three slots separating the four strips. A secondary coil includes three strips that are interlaced in the three slots between the four strips of the primary coil. By the nature of the diagram of FIG. 9, not all couplings are shown. Moreover, as such selected coupling depends upon design requirements, FIG. 9 does not attempt to illustrate all of the specific couplings of strips. Generally, however, for a configuration of interlaced strips, the strips may be coupled by traces formed over or under the shown strips. The number of coupled strips may readily be determined by one of average skill in the art without undue experimentation according to design requirements.

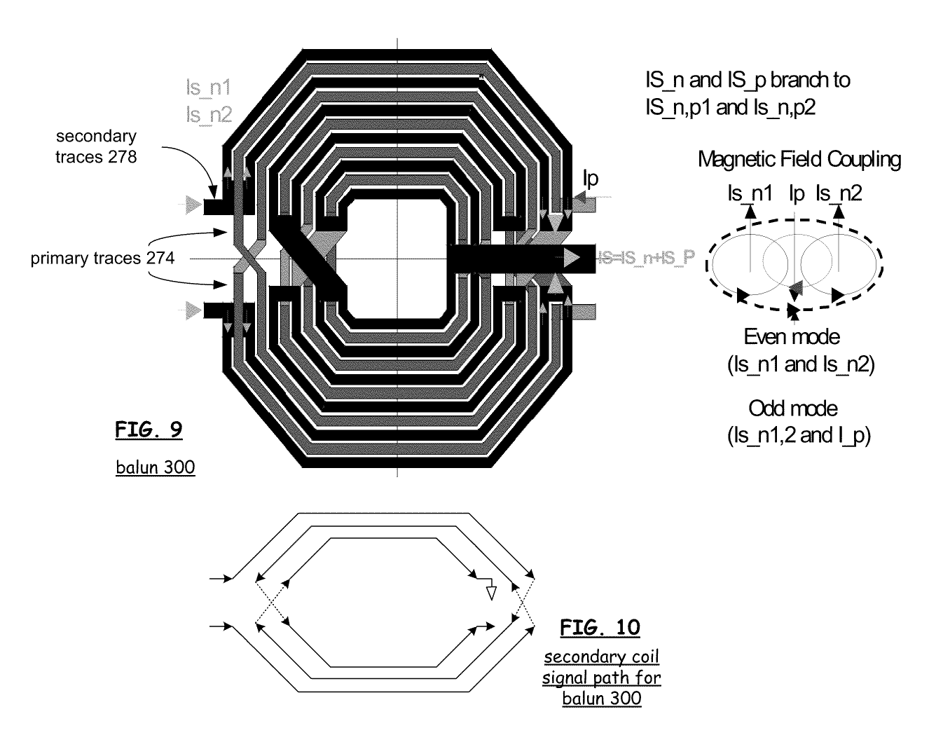

To assist in the understanding of FIG. 9, one possible secondary coil signal path is shown in FIG. 10. FIG. 10 is a signal flow diagram that illustrates one possible secondary coil signal path. It should also be noted that the designation of primary and secondary may be applied oppositely of that shown in FIG. 9. Generally, either may represent the balanced or unbalanced end of the balun.

One aspect of the embodiments of the baluns is that the balun structure is a passive structure for high power and low loss applications. In many current integrated circuit wireless transceiver designs, conductors have limited current handling capabilities. Thus, the baluns according to the embodiments of the invention for such applications typically comprises wide trace widths (relatively speaking) or high quality non-standard metal layers or both. Additionally, loss due to several factors including resonant resistance (substrate conductor loss) and to magnetic coupling (magnetic flux coupling) is reduced in the embodiments of the invention by distributing current in a small number of branches and by immersing one inductor structure into space between branches of another inductor structure. As such, resistive, inductive and capacitive losses are reduced.

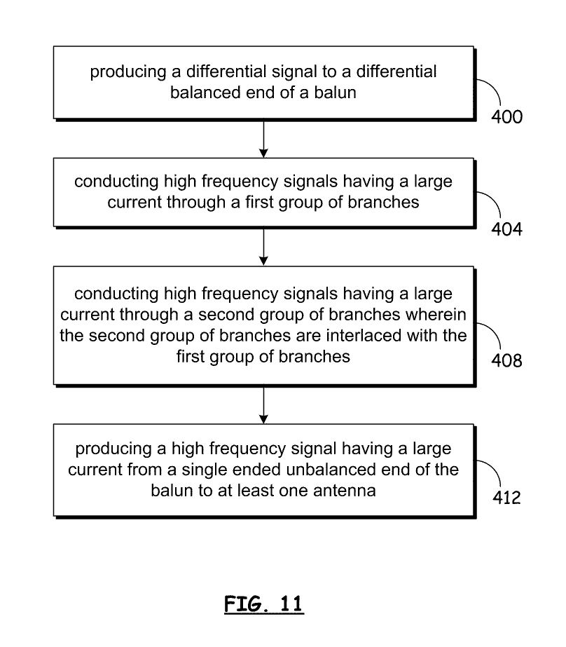

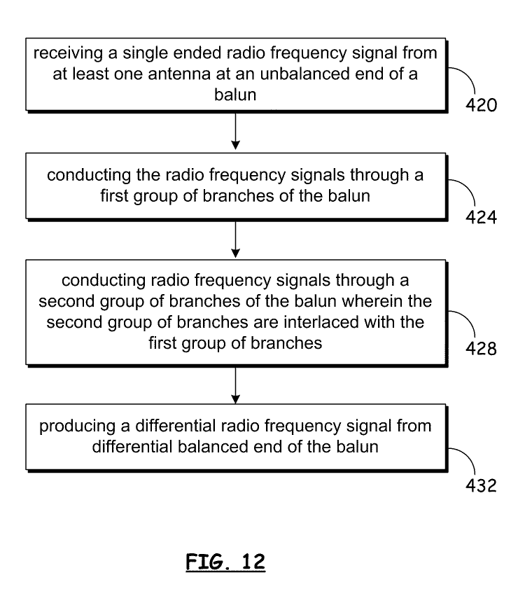

FIGS. 11 and 12 are flow charts that illustrate a method according to one embodiment of the invention. In FIG. 11, the illustrated method is a method in an integrated circuit radio transceiver that includes producing a differential signal to a differential balanced end of a balun (step 400) and conducting high frequency signals having a large current through a first group of branches (step 404). The method further includes conducting high frequency signals having a large current through a second group of branches wherein the second group of branches are interlaced with the first group of branches (step 408) and producing a high frequency signal having a large current from a single ended unbalanced end of the balun to at least one antenna (step 412). The current conducted through the first and second groups of branches are conducted in the same direction to define an even mode operation of the balun in one mode of operation and are conducted in an opposite direction to define an odd mode of operation of the balun in a different or second mode of operation.

Alternatively, the method in an integrated circuit radio transceiver includes receiving a single ended radio frequency signal from at least one antenna at an unbalanced end of a balun (step 420) and conducting the radio frequency signals through a first group of branches of the balun (step 424). The method further includes conducting radio frequency signals through a second group of branches of the balun wherein the second group of branches are interlaced with the first group of branches (step 428) and producing a differential radio frequency signal from differential balanced end of the balun (step 432). As before, the current conducted through the first and second groups of branches are conducted in the same direction to define an even mode operation of the balun and in an opposite direction to define an odd mode of operation of the balun.

As one of ordinary skill in the art will appreciate, the term “substantially” or “approximately”, as may be used herein, provides an industry-accepted tolerance to its corresponding term and/or relativity between items. Such an industry-accepted tolerance ranges from less than one percent to twenty percent and corresponds to, but is not limited to, component values, integrated circuit process variations, temperature variations, rise and fall times, and/or thermal noise. Such relativity between items ranges from a difference of a few percent to magnitude differences. As one of ordinary skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled”.

While the invention is susceptible to various modifications and alternative forms, specific embodiments thereof have been shown by way of example in the drawings and detailed description. It should be understood, however, that the drawings and detailed description thereto are not intended to limit the invention to the particular form disclosed, but, on the contrary, the invention is to cover all modifications, equivalents and alternatives falling within the spirit and scope of the present invention as defined by the claims. As may be seen, the described embodiments may be modified in many different ways without departing from the scope or teachings of the invention.

1. An integrated circuit radio transceiver, comprising:
baseband processor for processing ingoing and outgoing digital communication signals;
transmitter front end for processing and transmitting outgoing RF signals based upon the outgoing digital communication signals;
receiver front end for receiving ingoing RF signals and for processing the ingoing RF signals to produce the ingoing digital communication signals;
transmit-receive selection circuitry operably disposed to couple at least one antenna to the transmitter and receiver front end circuitry; and
a balun operably disposed to the transmit-receive circuitry and to one of the transmitter front end circuitry and the receiver front end circuitry, wherein the balun comprises a plurality of interlaced traces for conducting current.

2. The integrated circuit radio transceiver of claim 1 wherein the balun comprises two groups of traces that are operably disposed to conduct current in opposite directions.

3. The integrated circuit radio transceiver of claim 1 wherein the balun comprises two groups of traces that are operably disposed to conduct current in the same direction.

4. The integrated circuit radio transceiver of claim 1 wherein the balun comprises two groups of traces wherein a first group of traces is disposed in slots formed between traces of the second group of traces.

5. The integrated circuit radio transceiver of claim 1 wherein the balun comprises two groups of interlaced traces and wherein the first group has at least one more trace that the second group of traces.

6. The integrated circuit radio transceiver of claim 1 wherein the balun comprises two groups of interlaced traces and wherein the first group has twice as many traces as the second group of traces.

7. An integrated circuit radio transceiver, comprising:
baseband processor for processing ingoing and outgoing digital communication signals;
transmitter front end for processing and transmitting outgoing RF signals based upon the outgoing digital communication signals;
receiver front end for receiving ingoing RF signals and for processing the ingoing RF signals to produce the ingoing digital communication signals;
transmit-receive selection circuitry operably disposed to couple at least one antenna to the transmitter and receiver front end circuitry; and
a balun operably disposed to the transmit-receive circuitry and to one of the transmitter front end circuitry and the receiver front end circuitry, wherein the balun comprises a plurality of traces coupled at least at one end for conducting current in a first direction and at least one trace for conducting current in a second direction.

8. The integrated circuit radio transceiver of claim 7 wherein the balun comprises two interlaced traces operably disposed to conduct current in substantially opposite directions wherein the at least one trace for conducting current in the second direction is interlaced within spaces of the plurality of traces for conducting current in the first direction.

9. The integrated circuit radio transceiver of claim 7 wherein the balun comprises two interlaced traces operably disposed to conduct current in substantially similar directions wherein the at least one trace for conducting current in the second direction is interlaced within spaces of the plurality of traces for conducting current in the first direction.

10. The integrated circuit radio transceiver of claim 7 wherein the balun comprises two groups of traces wherein a first group of traces is disposed in slots formed between traces of the second group of traces.

11. The integrated circuit radio transceiver of claim 7 wherein the balun comprises two groups of interlaced traces arranged on a substrate surface in a coiled configuration.

12. The integrated circuit radio transceiver of claim 7 wherein the balun comprises two groups of interlaced traces and wherein a first group has twice as many traces as a second group of traces.

13. A method in an integrated circuit radio transceiver, comprising:
producing a differential signal to a differential balanced end of a balun;
conducting high frequency signals having a large current through a first group of branches;
conducting high frequency signals having a large current through a second group of branches wherein the second group of branches are interlaced with the first group of branches; and
producing a high frequency signal having a large current from a single ended unbalanced end of the balun to at least one antenna.

14. The method of claim 13 wherein the current conducted through the first and second groups of branches are conducted in the same direction to define an even mode operation of the balun.

15. The method of claim 13 wherein the current conducted through the first and second groups of branches are conducted in an opposite direction to define an odd mode of operation of the balun.

16. A method in an integrated circuit radio transceiver, comprising:
receiving a single ended radio frequency signal from at least one antenna at an unbalanced end of a balun;
conducting the radio frequency signals through a first group of branches of the balun;
conducting radio frequency signals through a second group of branches of the balun wherein the second group of branches are interlaced with the first group of branches; and
producing a differential radio frequency signal from differential balanced end of the balun.

17. The method of claim 16 wherein the current conducted through the first and second groups of branches are conducted in the same direction to define an even mode operation of the balun.

18. The method of claim 16 wherein the current conducted through the first and second groups of branches are conducted in an opposite direction to define an odd mode of operation of the balun.
